(19) United States
(12) Patent Application Publication
(10) Pub. No.: US 2024/0087920 A1
(43) Pub. Date: Mar. 14, 2024

(54) SUBSTRATE PROCESSING APPARATUS AND LEAK DETERMINATION METHOD FOR USE IN SUBSTRATE PROCESSING APPARATUS

(71) Applicant: SCREEN Holdings Co., Ltd., Kyoto (JP)

(72) Inventors: Mao OMORI, Kyoto (JP); Hiroshi MIYAKE, Kyoto (JP)

(21) Appl. No.: 18/451,625

(22) Filed: Aug. 17, 2023

(30) Foreign Application Priority Data
Sep. 8, 2022 (JP) 2022-142886

(51) Int. Cl. H01L 21/67; H01J 37/32; H01L 21/687

(52) U.S. Cl. CPC H01L 21/67115; H01J 37/32449; H01L 21/67276; H01L 21/68742; H01L 21/68785

(57) ABSTRACT

A leak determination method includes: a heating step of heating a semiconductor wafer in a chamber; a transport step of transporting the semiconductor wafer from the chamber after the heating step; a temperature measurement step of measuring an ambient temperature in the chamber; and a leak determination step of performing leak determination processing of the chamber. After the semiconductor wafer is transported from the chamber, waiting is continued until the ambient temperature decreases to a predetermined waiting specified temperature, and the leak determination processing is started when the ambient temperature reaches the waiting specified temperature.

### BACKGROUND OF THE INVENTION

### Field of the Invention

The present invention relates to a substrate processing apparatus for heating a laminar precision electronic substrate (hereinafter simply referred to as a “substrate”), such as a semiconductor wafer, and a leak determination method for use in the substrate processing apparatus.

### Description of the Background Art

In a process of manufacturing a semiconductor device, a substrate processing apparatus for heating a substrate is used. In such a substrate processing apparatus, flash lamp annealing (FLA) to heat a semiconductor wafer in an extremely short time is gaining attention. Flash lamp annealing is thermal processing technology of irradiating a surface of the semiconductor wafer with flashes of light using xenon flash lamps (simple “flash lamps” hereinafter refer to the xenon flash lamps) to increase a temperature of only the surface of the semiconductor wafer in an extremely short time (a few milliseconds or less).

Radiation spectral distribution of a xenon flash lamp is in an ultraviolet range to a near infrared range, has a shorter wavelength than that of a conventional halogen lamp, and substantially coincides with a fundamental absorption band of a semiconductor wafer made of silicon. Thus, when the semiconductor wafer is irradiated with the flashes of light from the xenon flash lamps, a temperature of the semiconductor wafer can rapidly be increased with less light being transmitted therethrough. Flash light irradiation in an extremely short time of a few milliseconds or less is also found to be able to selectively increase a temperature of only a portion near the surface of the semiconductor wafer.

Such flash lamp annealing is used in processing in which heating in an extremely short time is required, and is typically used for activation of impurities implanted into the semiconductor wafer, for example. When a surface of the semiconductor wafer into which impurities have been implanted by ion implantation is irradiated with flashes of light from the flash lamps, a temperature of the surface of the semiconductor wafer can be increased to an activation temperature only in an extremely short time, and only activation of the impurities can be performed without diffusing the impurities to a greater depth.

On the other hand, flash lamp annealing in an atmosphere of a reactive gas, such as ammonia, has also been attempted. Disclosed, for example, is post deposition annealing of a high dielectric constant gate insulating film (high-k film) in which an ammonia atmosphere is formed in a chamber housing a semiconductor wafer including the high dielectric constant gate insulating film while the chamber is maintained at a reduced pressure and the semiconductor wafer is irradiated with flushes of light for heating. The high dielectric constant gate insulating film is being developed as a new stack structure of field effect transistors along with a metal gate electrode using metal for a gate electrode to solve a problem of an increase in leak current caused with the progress of thinning of the gate insulating film.

In a flash lamp annealing apparatus disclosed in Japanese Patent Application Laid-Open No. 2019-046847, an atmosphere in a chamber is evacuated before supply of a reactive gas into the chamber to reduce a pressure in the chamber to approximately 100 Pa. Even after the end of flash heating processing, the pressure in the chamber is reduced to discharge the reactive gas. In such an apparatus for reducing the pressure in the chamber to a pressure less than an atmospheric pressure, a problem in that a leak in the chamber prevents reduction in pressure arises. In particular, when the reactive gas, such as ammonia, is handled, a problem of a leak of the hazardous reactive gas out of the chamber also arises when the leak is present in the chamber. It is thus important to detect the presence or absence of the leak in the chamber. A cause of the leak in the chamber of the flash lamp annealing apparatus includes breakage of a quartz window of the chamber, failure of piping for supply and exhaust to and from the chamber, and the like.

As a scheme of detecting the presence or absence of the leak, it is contemplated that a hardware configuration, such as a sensor, for detecting cracking is mounted to the quartz window, for example, but it might interfere with irradiation with flashes of light. To prepare for such a problem, Japanese Patent Application Laid-Open No. 2019-046847 discloses technology of determining the presence or absence of a leak in a chamber by whether a measured value of a pressure gauge reaches a target pressure even when an elapsed time since the start of reduction in pressure in the chamber by an exhaust unit exceeds a preset threshold. According to such technology disclosed in Japanese Patent Application Laid-Open No. 2019-046847, the elapsed time since the start of reduction in pressure is monitored to determine the leak, so that the presence or absence of the leak in the chamber can be detected with a simple configuration.

However, the amount of the leak and a gas discharge efficiency vary depending on a temperature in the chamber, so that accuracy of leak determination might be reduced depending on the temperature in the chamber. For example, when the temperature in the chamber is high, a temperature of a gas present in the chamber is also high, so that a gas density is low. When the gas density decreases, the gas discharge efficiency increases, whereas the amount of the leak when the gas is contained in the chamber tends to increase. When a minute amount of the leak is detected, such behavior of the gas depending on the temperature might cause false detection.

The present invention has been conceived in view of the above-mentioned problem, and it is an object of the present invention to provide a substrate processing apparatus capable of detecting the presence or absence of a leak in a chamber with accuracy and a leak determination method for use in the substrate processing apparatus.

### SUMMARY

The present invention is directed to a substrate processing apparatus for heating a laminar precision electronic substrate (hereinafter simply referred to as a “substrate”), such as a semiconductor wafer, and a leak determination method for use in the substrate processing apparatus.

In one aspect of the present invention, a leak determination method for use in a substrate processing apparatus for heating a substrate housed in a chamber includes: a heating step of heating the substrate in the chamber; a transport step of transporting the substrate from the chamber after the heating step; a temperature measurement step of measuring an ambient temperature in the chamber; and a leak determination step of performing leak determination processing of the chamber, wherein after the substrate is transported from the chamber, waiting is continued until the ambient temperature decreases to a predetermined waiting specified temperature, and the leak determination processing is started when the ambient temperature reaches the waiting specified temperature.

After the substrate is transported from the chamber, waiting is continued until the ambient temperature decreases to the predetermined waiting specified temperature, and the leak determination processing is started when the ambient temperature reaches the waiting specified temperature, so that the presence or absence of the leak in the chamber can be detected with accuracy.

In the present invention, a start of a second time period is preferably later than a start of a containment time period during which supply and discharge of gas into and from the chamber are stopped, and an end of the containment time period and an end of the second time period preferably coincide with each other.

The start of the second time period is later than the start of the containment time period, and the end of the containment time period and the end of the second time period coincide with each other, so that the leak determination processing can be performed after stopping of supply and discharge of gas is stabilized in the second time period. The presence or absence of the leak in the chamber can thus be detected with accuracy.

In the present invention, the waiting specified temperature is preferably higher than a room temperature, the leak determination method preferably further includes a table creation step of creating a correspondence table in which the waiting specified temperature and at least one of the first threshold and the second threshold are associated with each other, and, in the leak determination step, at least one of the first threshold and the second threshold corresponding to the waiting specified temperature as specified is preferably extracted from the correspondence table to perform the leak determination processing.

At least one of the first threshold and the second threshold corresponding to the waiting specified temperature as specified is extracted from the correspondence table to perform the leak determination processing, so that the leak determination processing is performed using the first threshold or the second threshold corresponding to a temperature at which the leak determination processing is performed. The presence or absence of the leak in the chamber can thus be detected with accuracy.

In the present invention, when the substrate is being heated in the chamber at reaching time set in a scheduling step, the leak determination processing is preferably started after heating of the substrate ends and the substrate is transported from the chamber.

The leak determination processing is started after heating of the substrate ends and the substrate is transported from the chamber. The leak determination processing of the chamber is thus always performed with no substrate in the chamber. The presence or absence of the leak in the chamber can thus be detected with accuracy.

In another aspect of the present invention, a substrate processing apparatus for heating a substrate includes: a chamber to house the substrate; a heating unit to heat the substrate housed in the chamber; a gas supply unit to supply gas into the chamber; a gas discharge unit to discharge gas from the chamber; a thermometer to measure an ambient temperature in the chamber; a pressure gauge to measure a pressure in the chamber, wherein after the substrate whose heating has ended is transported from the chamber, waiting is continued until the ambient temperature decreases to a predetermined waiting specified temperature, and leak determination processing of the chamber is started when the ambient temperature reaches the waiting specified temperature.

After the substrate is transported from the chamber, waiting is continued until the ambient temperature decreases to the predetermined waiting specified temperature, and leak determination processing is started when the ambient temperature reaches the waiting specified temperature, so that the presence or absence of the leak in the chamber can be detected with accuracy.

In the present invention, a start of the second time period is preferably later than a start of a containment time period during which supply and discharge of gas into and from the chamber are stopped, and an end of the containment time period and an end of the second time period preferably coincide with each other.

The start of the second time period is later than the start of the containment time period, and the end of the containment time period and the end of the second time period coincide with each other, so that the leak determination processing can be performed after stopping of supply and discharge of gas is stabilized in the second time period. The presence or absence of the leak in the chamber can thus be detected with accuracy.

In the present invention, the waiting specified temperature is preferably higher than a room temperature, the substrate processing apparatus preferably further includes a storage to store a correspondence table in which the waiting specified temperature and at least one of the first threshold and the second threshold are associated with each other, and at least one of the first threshold and the second threshold corresponding to the waiting specified temperature as specified is preferably extracted from the correspondence table to perform the leak determination processing.

At least one of the first threshold and the second threshold corresponding to the waiting specified temperature as specified is extracted from the correspondence table to perform the leak determination processing, so that the leak determination processing is performed using the first threshold or the second threshold corresponding to a temperature at which the leak determination processing is performed. The presence or absence of the leak in the chamber can thus be detected with accuracy.

In the present invention, when the substrate is being heated in the chamber at reaching the time set by a scheduling unit, the leak determination processing is preferably started after heating of the substrate ends and the substrate is transported from the chamber.

The leak determination processing is started after heating of the substrate ends and the substrate is transported from the chamber. The leak determination processing of the chamber is thus always performed with no substrate in the chamber. The presence or absence of the leak in the chamber can thus be detected with accuracy.

It is thus an object of the present invention to provide a substrate processing apparatus capable of detecting the presence or absence of a leak in a chamber with accuracy and a leak determination method for use in the substrate processing apparatus.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal cross-sectional view illustrating a configuration of a substrate processing apparatus according to the present invention;

FIG. 2 is a perspective view illustrating appearance of a holding unit as a whole;

FIG. 3 is a plan view of a susceptor;

FIG. 4 is a cross-sectional view of the susceptor;

FIG. 5 is a plan view of a transfer mechanism;

FIG. 6 is a side view of the transfer mechanism;

FIG. 7 is a plan view illustrating arrangement of a plurality of halogen lamps;

FIG. 8 is a diagram illustrating a supply and exhaust mechanism with respect to a chamber;

FIG. 9 is a block diagram showing a relationship between a controller and each unit;

FIG. 10 is a flowchart showing a flow of leak determination processing according to the present invention;

FIG. 11 is a flowchart showing a flow of first determination processing according to the present invention;

FIG. 12 is a diagram showing a pressure change in the chamber in first determination;

FIG. 13 is a flowchart showing a flow of second determination processing according to the present invention;

FIG. 14 is a diagram showing a pressure change in the chamber in second determination; and

FIG. 15 is a diagram showing a correspondence table in which a waiting specified temperature and first to fourth thresholds are associated with each other.

### DESCRIPTION OF THE PREFERRED EMBODIMENTS

Embodiments will be described below with reference to the accompanying drawings. In the embodiments below, detailed features and the like are shown for description of technology, but they are examples and are all not necessary features to implement the embodiments.

The drawings are schematically shown, and configurations are omitted or simplified in the drawings as appropriate for convenience of description. The sizes of and a positional relationship among configurations shown in different drawings are not necessarily accurate, and can be changed as appropriate. Hatching is sometimes applied to drawings other than a cross-sectional view, such as a plan view, for ease of understanding of the embodiments.

In description made below, similar components bear the same reference signs, and have similar names and functions. Detailed description thereof is thus sometimes omitted to avoid redundancy.

In description made below, an expression “comprising”, “including”, or “having” a certain component is not an exclusive expression excluding the presence of the other components unless otherwise noted.

Even if ordinal numbers, such as “first” and “second”, are used in description made below, these terms are used for the sake of convenience for ease of understanding of the embodiments, and an order is not limited to an order that can be represented by the ordinal numbers and the like.

### First Embodiment

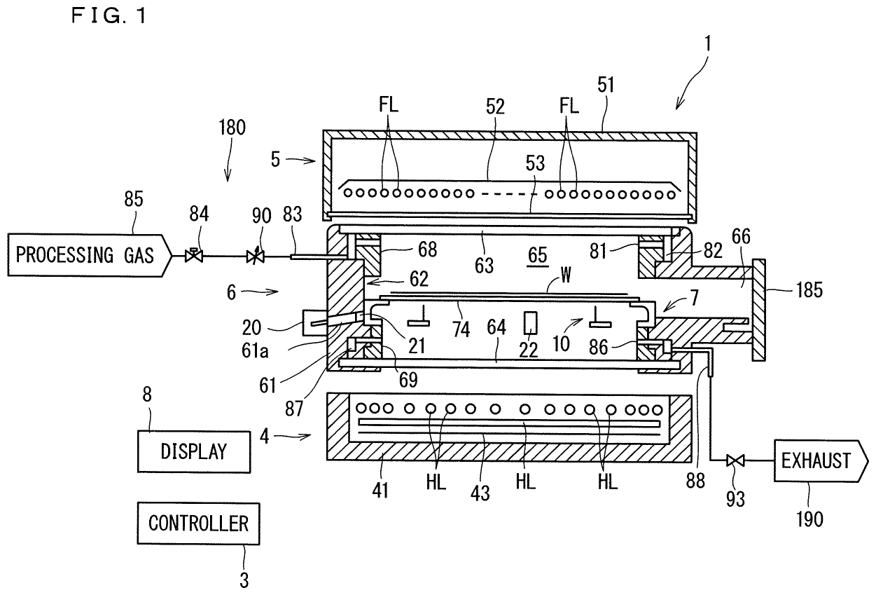

FIG. 1 is a longitudinal cross-sectional view illustrating a configuration of a thermal processing apparatus 1 as a substrate processing apparatus according to the present invention. The thermal processing apparatus 1 in FIG. 1 is an apparatus for heating a substrate housed in a chamber 6. More specifically, the thermal processing apparatus 1 is a flash lamp annealing apparatus that irradiates a disk-shaped semiconductor wafer W as the substrate with flashes of light to heat the semiconductor wafer W. The size of the semiconductor wafer W to be processed is not particularly limited, but the semiconductor wafer W has a diameter of 300 mm or 450 mm (300 mm in the present embodiment), for example. The semiconductor wafer W before being transported to the thermal processing apparatus 1 includes a high dielectric constant film (high-k film) as a gate insulating film, and post deposition annealing (PDA) of the high dielectric constant film is performed by heating performed by the thermal processing apparatus 1. In FIG. 1 and the drawings thereafter, dimensions and the number of components are exaggerated or simplified as necessary for ease of understanding.

The thermal processing apparatus 1 includes the chamber 6 to house the semiconductor wafer W, a halogen heating unit 4 to irradiate the semiconductor wafer W with light, and a flash heating unit 5 to irradiate the semiconductor wafer W with flashes of light. The halogen heating unit 4 incorporates a plurality of halogen lamps HL as continuous lighting lamps. The flash heating unit 5 incorporates a plurality of flash lamps FL. The flash heating unit 5 is disposed above the chamber 6, and the halogen heating unit 4 is disposed below the chamber 6. The flash heating unit 5 and the halogen heating unit 4 heat the semiconductor wafer W housed in the chamber 6. The thermal processing apparatus 1 also includes, within the chamber 6, a holding unit 7 to hold the semiconductor wafer W in a horizontal orientation and a transfer mechanism 10 to transfer the semiconductor wafer W between the holding unit 7 and an outside of the apparatus. The thermal processing apparatus 1 further includes a controller 3 to control each operation mechanism disposed in the halogen heating unit 4, the flash heating unit 5, and the chamber 6 to perform thermal processing of the semiconductor wafer W. The thermal processing apparatus 1 also includes a display 8 to display the status of processing of the thermal processing apparatus 1 and a set screen for various processing conditions. The display 8 includes a liquid crystal display (an LCD) panel or an organic electroluminescence (EL) panel, for example.

The chamber 6 includes a tubular chamber side portion 61 and chamber windows made of quartz attached to the top and bottom of the chamber side portion 61. The chamber side portion 61 has a substantially tubular shape with its top and bottom opened. An upper chamber window 63 is attached to an upper opening for blocking, and a lower chamber window 64 is attached to a lower opening for blocking. The upper chamber window 63 forming a ceiling of the chamber 6 is a disk-shaped member made of quartz, and functions as a quartz window that transmits flashes of light emitted from the flash heating unit 5 into the chamber 6. The lower chamber window 64 forming a floor of the chamber 6 is also a disk-shaped member made of quartz, and functions as a quartz window that transmits light from the halogen heating unit 4 into the chamber 6.

A reflective ring 68 and a reflective ring 69 are respectively attached to an upper portion and a lower portion of an inner wall surface of the chamber side portion 61. The reflective rings 68 and 69 are each formed to be annular. The reflective ring 68 on an upper side is attached by being fit from above the chamber side portion 61. On the other hand, the reflective ring 69 on a lower side is attached by being fit from below the chamber side portion 61, and fastened with screws, which are not illustrated. That is to say, the reflective rings 68 and 69 are both removably attached to the chamber side portion 61. An internal space of the chamber 6, that is, a space enclosed by the upper chamber window 63, the lower chamber window 64, the chamber side portion 61, and the reflective rings 68 and 69 is defined as a thermal processing space 65.

By attaching the reflective rings 68 and 69 to the chamber side portion 61, a recess 62 is formed in an inner wall surface of the chamber 6. That is to say, the recess 62 surrounded by a central portion of the inner wall surface of the chamber side portion 61 to which the reflective rings 68 and 69 have not been attached, a lower end surface of the reflective ring 68, and an upper end surface of the reflective ring 69 is formed. The recess 62 is formed in the inner wall surface of the chamber 6 to be annular along a horizontal direction, and surrounds the holding unit 7 to hold the semiconductor wafer W. The chamber side portion 61 and the reflective rings 68 and 69 are each made of a metallic material (e.g., stainless steel) having high strength and excellent heat resistance. The chamber side portion 61 has a transport opening (furnace mouth) 66 to transport the semiconductor wafer W to and from the chamber 6. The transport opening 66 is openable and closable by a gate valve 185. The transport opening 66 is connected in communication with an outer circumferential surface of the recess 62. The semiconductor wafer W can thus be transported from the transport opening 66 to the thermal processing space 65 through the recess 62 and be transported from the thermal processing space 65 when the gate valve 185 opens the transport opening 66. The thermal processing space 65 in the chamber 6 becomes an enclosed space when the gate valve 185 closes the transport opening 66.

Furthermore, the chamber side portion 61 has a through hole 61a. A radiation thermometer 20 is attached to a portion of an outer wall surface of the chamber side portion 6 having the through hole 61a. The through hole 61a is a cylindrical hole to guide infrared light radiated from a lower surface of the semiconductor wafer W held by a susceptor 74, which will be described below, to the radiation thermometer 20. The through hole 61a is inclined with respect to the horizontal direction so that an axis thereof in a direction of penetration intersects a main surface of the semiconductor wafer W held by the susceptor 74. A transparent window 21 made of a barium fluoride material that transmits infrared light in a wavelength region measurable by the radiation thermometer 20 is attached to an end of the through hole 61a facing the thermal processing space 65.

An ambient thermometer 22 is disposed in the chamber 6. The ambient thermometer 22 includes a thermocouple, for example, and measures an ambient temperature in the thermal processing space 65 in the chamber 6 (a temperature measurement step). While the ambient thermometer 22 is illustrated to be disposed in the chamber 6 in FIG. 1 for convenience of illustration, the ambient thermometer 22 may be attached to the chamber side portion 61 as with the radiation thermometer 20.

A gas supply hole 81 to supply a processing gas (a nitrogen gas (N₂) and ammonia (NH₃) in the present embodiment) to the thermal processing space 65 is formed in an upper portion of an inner wall of the chamber 6. The gas supply hole 81 is formed at a position above the recess 62, and may be formed in the reflective ring 68. The gas supply hole 81 is connected in communication with a gas supply tube 83 through a buffer space 82 formed to be annular within a side wall of the chamber 6. The gas supply tube 83 is connected to a processing gas supply source 85. The processing gas supply source 85 supplies, as the processing gas, the nitrogen gas or a mixture of ammonia and the nitrogen gas to the gas supply tube 83 under control performed by the controller 3. A supply valve 84 and a flow rate regulation valve 90 are inserted along a path of the gas supply tube 83. When the supply valve 84 is opened, the processing gas is supplied from the processing gas supply source 85 to the buffer space 82. A flow rate of the processing gas flowing through the gas supply tube 83 and supplied to the buffer space 82 is regulated by the flow rate regulation valve 90. The flow rate of the processing gas defined by the flow rate regulation valve 90 is variable due to control performed by the controller 3. The processing gas having flowed into the buffer space 82 flows to spread in the buffer space 82 having a lower fluid resistance than the gas supply hole 81, and is supplied through the gas supply hole 81 into the thermal processing space 65. The processing gas supply source 85, the supply valve 84, and the flow rate regulation valve 90 constitute a gas supply unit 180 to supply a predetermined processing gas into the chamber 6. The processing gas is not limited to the nitrogen gas and ammonia, and may be an inert gas, such as argon (Ar) and helium (He), or a reactive gas, such as oxygen (O₂), hydrogen (H₂), chlorine (Cl₂), hydrogen chloride (HCl), ozone (O₃), nitrogen monoxide (NO), nitrous oxide (N₂O), and nitrogen dioxide (NO₂).

On the other hand, a gas exhaust hole 86 to exhaust (discharge) gas in the thermal processing space 65 is formed in a lower portion of the inner wall of the chamber 6. The gas exhaust hole 86 is formed at a position below the recess 62, and may be formed in the reflective ring 69. The gas exhaust hole 86 is connected in communication with a gas exhaust tube 88 through a buffer space 87 formed to be annular within the side wall of the chamber 6. The gas exhaust tube 88 is connected to an exhaust unit 190.

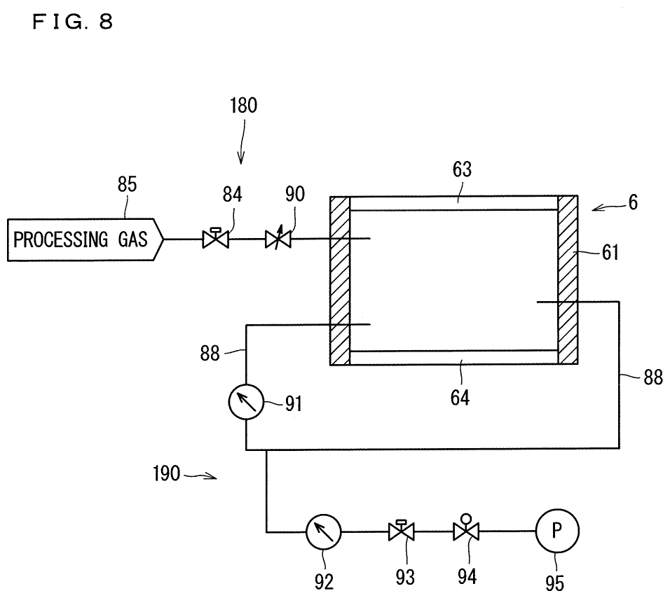

FIG. 8 is a diagram illustrating a supply and exhaust mechanism with respect to the chamber 6. The exhaust unit 190 includes a self-regulation valve pressure gauge 91, a vacuum pressure gauge 92, an exhaust valve 93, a pressure self-regulation valve 94, and a vacuum pump 95. As illustrated in FIG. 8, two gas exhaust tubes 88 (only one gas exhaust tube 88 is illustrated in FIG. 1) are connected to the chamber 6 on a side of the transport opening 66 and on a side opposite the side of the transport opening 66, and merge and are connected to the vacuum pump 95. The self-regulation valve pressure gauge 91, the vacuum pressure gauge 92, the exhaust valve 93, and the pressure self-regulation valve 94 are arranged along a path of the gas exhaust tubes 88.

The vacuum pump 95 is a pump that can reduce a pressure in the chamber 6 to at least 100 Pa or less through the gas exhaust tubes 88. The exhaust valve 93 is a valve, such as a solenoid valve, to open and close the path of the gas exhaust tubes 88, for example. When the exhaust valve 93 is opened while the vacuum pump 95 is activated, an atmosphere in the chamber 6 is withdrawn through the gas exhaust hole 86 and is evacuated through the buffer space 87 to the gas exhaust tubes 88. The vacuum pressure gauge 92 measures a pressure of the gas exhaust tubes 88 to measure the pressure in the chamber 6.

The self-regulation valve pressure gauge 91 and the pressure self-regulation valve 94 cooperate to maintain the pressure in the chamber 6 at a predetermined value. The self-regulation valve pressure gauge 91 also measures the pressure of the gas exhaust tubes 88 to measure the pressure in the chamber 6. The controller 3 provides the pressure self-regulation valve 94 with a set value (an indicated value) of the pressure in the chamber 6. The self-regulation valve pressure gauge 91 measures the pressure in the chamber 6 with the exhaust valve 93 being opened while the vacuum pump 95 is activated, and, based on the measured value, the pressure self-regulation valve 94 controls opening to regulate the pressure in the chamber 6 at the above-mentioned set value. That is to say, the pressure self-regulation valve 94 performs feedback control of the opening so that the pressure in the chamber 6 has the above-mentioned set value based on a result of measurement of the pressure in the chamber 6 by the self-regulation valve pressure gauge 91.

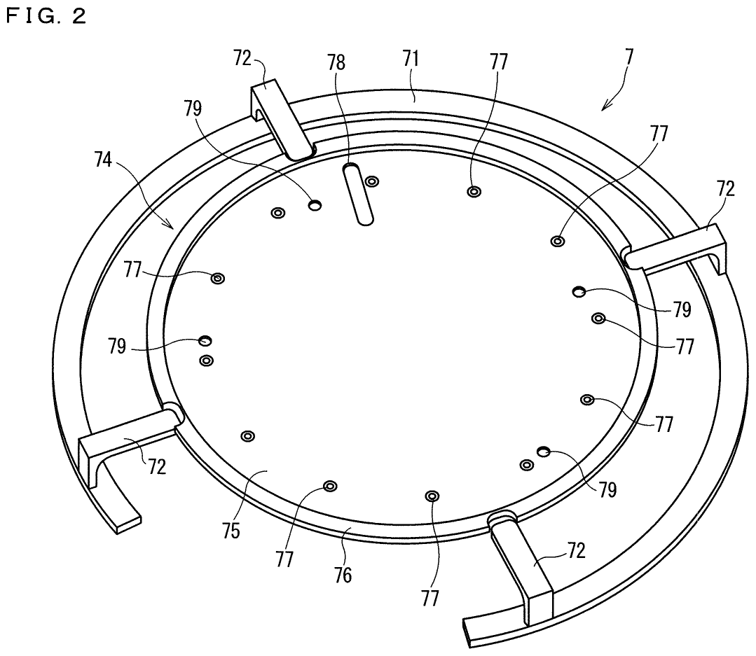

FIG. 2 is a perspective view illustrating appearance of the holding unit 7 as a whole. The holding unit 7 includes a base ring 71, connectors 72, and the susceptor 74. The base ring 71, the connectors 72, and the susceptor 74 are each made of quartz. That is to say, the holding unit 7 as a whole is made of quartz.

The base ring 71 is a quartz member having an arc shape that is a partially-missing annular shape. The missing portion is provided to prevent interference between transfer arms 11 of the transfer mechanism 10, which will be described below, and the base ring 71. The base ring 71 is mounted on a bottom surface of the recess 62 to be supported by a wall surface of the chamber 6 (see FIG. 1). The plurality of (four in the present embodiment) connectors 72 are arranged to stand on an upper surface of the base ring 71 along the circumference of the annular shape thereof. The connectors 72 are also quartz members, and are fixed to the base ring 71 by welding.

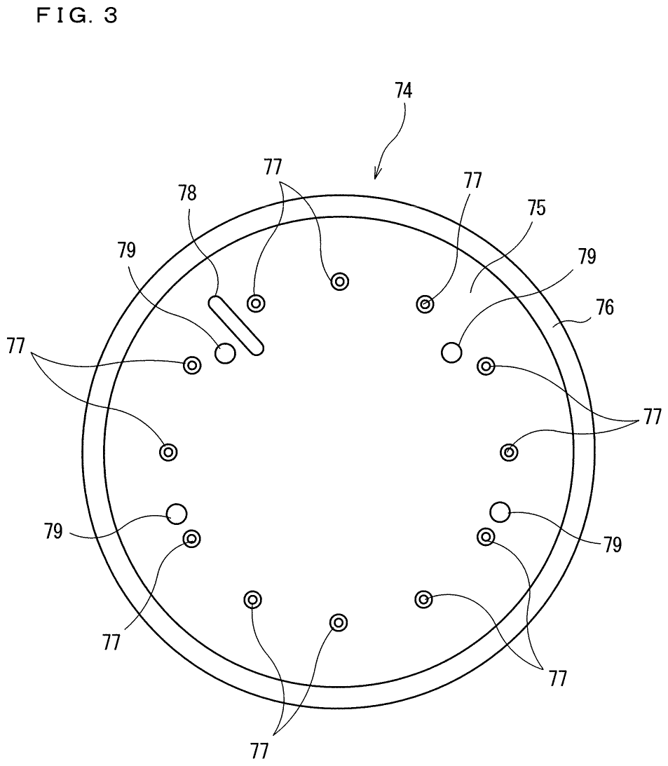

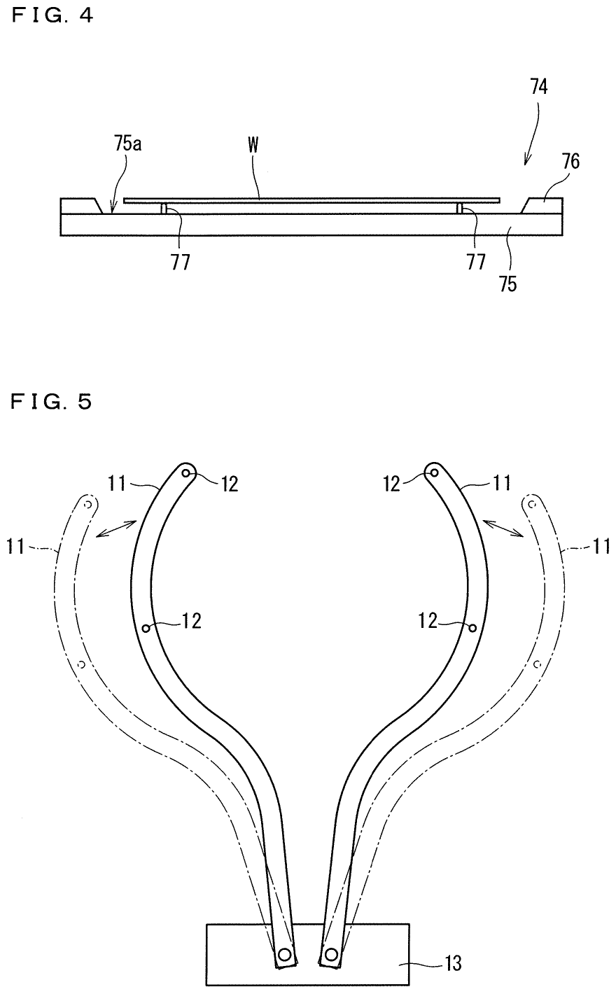

The susceptor 74 is supported by the four connectors 72 arranged on the base ring 71. FIG. 3 is a plan view of the susceptor 74. FIG. 4 is a cross-sectional view of the susceptor 74. The susceptor 74 includes a holding plate 75, a guide ring 76, and a plurality of substrate support pins 77. The holding plate 75 is a substantially circular planar member made of quartz. The holding plate 75 has a greater diameter than the semiconductor wafer W. That is to say, the holding plate 75 has a greater planar size than the semiconductor wafer W.

The guide ring 76 is disposed at a periphery of an upper surface of the holding plate 75. The guide ring 76 is an annular member having an inner diameter greater than the diameter of the semiconductor wafer W. For example, the guide ring 76 has an inner diameter of 320 mm when the semiconductor wafer W has a diameter of 300 mm. An inner circumference of the guide ring 76 is a tapered surface widening upward from the holding plate 75. The guide ring 76 is made of quartz as with the holding plate 75. The guide ring 76 may be welded onto the upper surface of the holding plate 75 or may be fixed to the holding plate 75 with pins and the like processed separately. Alternatively, the holding plate 75 and the guide ring 76 may be processed as an integral member.

A region of the upper surface of the holding plate 75 inward of the guide ring 76 is a planar holding surface 75a to hold the semiconductor wafer W. The plurality of substrate support pins 77 are arranged to stand on the holding surface 75a of the holding plate 75. In the present embodiment, a total of 12 substrate support pins 77 are arranged at 30° intervals to stand along a circumference of a circle concentric with an outer circumference of the holding surface 75a (the inner circumference of the guide ring 76). The diameter of the circle along which the 12 substrate support pins 77 are arranged (the distance between opposite substrate support pins 77) is smaller than the diameter of the semiconductor wafer W, and is 270 mm to 280 mm (270 mm in the present embodiment) when the semiconductor wafer W has a diameter of 300 mm. The substrate support pins 77 are each made of quartz. The plurality of substrate support pins 77 may be arranged on the upper surface of the holding plate 75 by welding, or may processed to be integral with the holding plate 75.

Referring back to FIG. 2, the four connectors 72 arranged to stand on the base ring 71 and the periphery of the holding plate 75 of the susceptor 74 are fixed by welding. That is to say, the susceptor 74 and the base ring 71 are fixedly connected by the connectors 72. The base ring 71 of the holding unit 7 as described above is supported by the wall surface of the chamber 6 to attach the holding unit 7 to the chamber 6. When the holding unit 7 is attached to the chamber 6, the holding plate 75 of the susceptor 74 is in the horizontal orientation (in an orientation in which a normal thereto coincides with a vertical direction). That is to say, the holding surface 75a of the holding plate 75 is a horizontal surface.

The semiconductor wafer W transported to the chamber 6 is mounted and held on the susceptor 74 of the holding unit 7 attached to the chamber 6 in the horizontal orientation. In this case, the semiconductor wafer W is supported by the 12 substrate support pins 77 arranged to stand on the holding plate 75 to be held by the susceptor 74. More strictly, upper ends of the 12 substrate support pins 77 are in contact with the lower surface of the semiconductor wafer W to support the semiconductor wafer W. The 12 substrate support pins 77 have a uniform height (the distance from the upper ends of the substrate support pins 77 to the holding surface 75a of the holding plate 75), and thus can support the semiconductor wafer W in the horizontal orientation.

The semiconductor wafer W is to be supported by the plurality of substrate support pins 77 while being spaced apart from the holding surface 75a of the holding plate 75 by a predetermined distance. The thickness of the guide ring 76 is greater than the height of each of the substrate support pins 77. Misalignment in the horizontal direction of the semiconductor wafer W supported by the plurality of substrate support pins 77 is thus prevented by the guide ring 76.

As illustrated in FIGS. 2 and 3, the holding plate 75 of the susceptor 74 has an opening 78 vertically passing through the holding plate 75. The opening 78 is formed for the radiation thermometer 20 to receive light (infrared light) radiated from the lower surface of the semiconductor wafer W. That is to say, the radiation thermometer 20 receives light radiated from the lower surface of the semiconductor wafer W through the opening 78 and the transparent window 21 attached to the through hole 61a of the chamber side portion 61, and measures a temperature of the semiconductor wafer W. The holding plate 75 of the susceptor 74 further has four through holes 79 through which lift pins 12 of the transfer mechanism 10, which will be described below, penetrate for a transfer of the semiconductor wafer W.

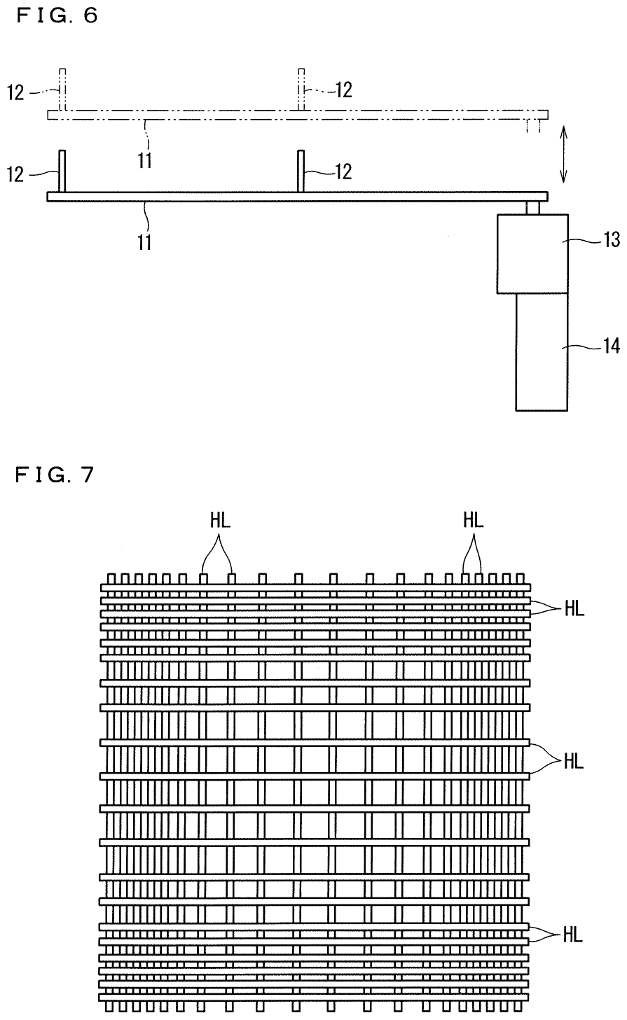

FIG. 5 is a plan view of the transfer mechanism 10. FIG. 6 is a side view of the transfer mechanism 10. The transfer mechanism 10 includes two transfer arms 11. The transfer arms 11 have an arc shape substantially along the recess 62 formed to be annular. Two lift pins 12 are arranged to stand on each of the transfer arms 11. The transfer arms 11 and the lift pins 12 are each made of quartz. The transfer arms 11 are each pivotable by a horizontal movement mechanism 13. The horizontal movement mechanism 13 horizontally moves the pair of transfer arms 11 between a transfer operation position (a position in solid lines in FIG. 5) where the semiconductor wafer W is transferred to and from the holding unit 7 and a withdrawal position (a position in alternate long and short dashed lines in FIG. 5) where the pair of transfer arms 11 does not overlap the semiconductor wafer W held by the holding unit 7 in plan view. The horizontal movement mechanism 13 may pivot the respective transfer arms 11 by separate motors, or may pivot the transfer arms 11 in conjunction with each other using a link mechanism by a single motor.

The pair of transfer arms 11 is moved upward and downward by a lift mechanism 14 along with the horizontal movement mechanism 13. When the lift mechanism 14 moves the pair of transfer arms 11 upward at the transfer operation position, a total of four lift pins 12 pass through the through holes 79 (see FIGS. 2 and 3) formed in the susceptor 74, and upper ends of the lift pins 12 protrude from an upper surface of the susceptor 74. On the other hand, when the lift mechanism 14 moves the pair of transfer arms 11 downward at the transfer operation position to draw the lift pins 12 from the through holes 79, and the horizontal movement mechanism 13 moves the pair of transfer arms 11 to open the transfer arms 11, the transfer arms 11 are moved to the withdrawal position. The withdrawal position of the pair of transfer arms 11 is directly above the base ring 71 of the holding unit 7. Since the base ring 71 is mounted on the bottom surface of the recess 62, the withdrawal position of the transfer arms 11 is inside the recess 62. An exhaust mechanism, which is not illustrated, is disposed near a position at which a drive unit (the horizontal movement mechanism 13 and the lift mechanism 14) of the transfer mechanism 10 is disposed to discharge an atmosphere around the drive unit of the transfer mechanism 10 to an outside of the chamber 6.

Referring back to FIG. 1, the flash heating unit 5 disposed above the chamber 6 includes, within a housing 51, a light source including a plurality of (30 in the present embodiment) xenon flash lamps FL and a reflector 52 disposed to cover the light source from above. A lamp light radiation window 53 is attached to the bottom of the housing 51 of the flash heating unit 5. The lamp light radiation window 53 forming a floor of the flash heating unit 5 is a plate-like quartz window made of quartz. The flash heating unit 5 is installed above the chamber 6, so that the lamp light radiation window 53 opposes the upper chamber window 63. The flash lamps FL irradiate the thermal processing space 65 with flashes of light from above the chamber 6 through the lamp light radiation window 53 and the upper chamber window 63.

The plurality of flash lamps FL are each a rod-like lamp having an elongated cylindrical shape, and are in planar arrangement so that longitudinal directions thereof are parallel to one another along the main surface of the semiconductor wafer W held by the holding unit 7 (i.e., along the horizontal direction). A plane formed by arrangement of the flash lamps FL is thus a horizontal plane. A region in which the plurality of flash lamps FL are arranged is greater than a planar size of the semiconductor wafer W.

Each of the xenon flash lamps FL includes a rod-like glass tube (discharge tube) in which a xenon gas is enclosed and which includes, at opposite ends thereof, an anode and a cathode connected to a capacitor, and a trigger electrode attached to an outer circumferential surface of the glass tube. The xenon gas is electrically an insulator, so that electricity does not flow through the glass tube in a normal state even if electric charge is accumulated in the capacitor. When a high voltage is applied to the trigger electrode to cause electrical breakdown, however, electricity stored in the capacitor instantaneously flows through the glass tube, and light is emitted by excitation of atoms or molecules of xenon at the time. In such a xenon flash lamp FL, electrostatic energy stored in advance in the capacitor is converted into an extremely short light pulse of 0.1 ms to 100 ms, so that the xenon flash lamp FL has a feature of being capable of emitting extremely intense light compared with a continuous lighting light source, such as a halogen lamp HL. That is to say, the flash lamp FL is a pulsed light emitting lamp momentarily emitting light in an extremely short time of less than one second. A light emitting time of the flash lamp FL is adjustable by a coil constant of a lamp power supply to supply power to the flash lamp FL.

The reflector 52 is disposed above the plurality of flash lamps FL to cover the flash lamps FL as a whole. A basic function of the reflector 52 is to reflect flashes of light emitted from the plurality of flash lamps FL toward the thermal processing space 65. The reflector 52 is formed of an aluminum alloy plate, and has a surface (a surface facing the flash lamps FL) having been roughened by blasting.

The halogen heating unit 4 disposed below the chamber 6 incorporates the plurality of (40 in the present embodiment) halogen lamps HL within a housing 41. The halogen heating unit 4 irradiates the thermal processing space 65 with light from below the chamber 6 through the lower chamber window 64 using the plurality of halogen lamps HL to heat the semiconductor wafer W (a preheating step).

FIG. 7 is a plan view illustrating arrangement of the plurality of halogen lamps HL. The 40 halogen lamps HL are arranged separately in two tiers. In an upper tier closer to the holding unit 7, 20 halogen lamps HL are arranged, and, in a lower tier farther from the holding unit 7 than the upper tier is, 20 halogen lamps HL are arranged. The halogen lamps HL are each a rod-like lamp having an elongated cylindrical shape. The 20 halogen lamps HL in each of the upper and lower tiers are arranged so that longitudinal directions thereof are parallel to one another along the main surface of the semiconductor wafer W held by the holding unit 7 (i.e., along the horizontal direction). A plane formed by arrangement of the halogen lamps HL in each of the upper and lower tiers is thus a horizontal plane.

As illustrated in FIG. 7, the halogen lamps HL arranged in each of the upper and lower tiers are denser in a region opposing the periphery of the semiconductor wafer W held by the holding unit 7 than in a region opposing a central portion of the semiconductor wafer W held by the holding unit 7. That is to say, the halogen lamps HL arranged in each of the upper and lower tiers have a shorter pitch at a periphery than in a central portion of lamp arrangement. The periphery of the semiconductor wafer W at which the temperature is likely to decrease during heating due to light irradiation by the halogen heating unit 4 can thus be irradiated with a greater amount of light.

The halogen lamps HL are arranged so that the halogen lamps HL in the upper tier and the halogen lamps HL in the lower tier intersect each other in a grid. That is to say, a total of 40 halogen lamps HL are arranged so that the longitudinal directions of the 20 halogen lamps HL arranged in the upper tier and the longitudinal directions of the 20 halogen lamps HL arranged in the lower tier are orthogonal to each other.

Each of the halogen lamps HL is a filament light source causing a filament disposed within a glass tube to glow by allowing a current to pass therethrough to thereby emit light. Gas obtained by introducing traces of halogen elements (iodide, bromine, and the like) into an inert gas, such as nitrogen and argon, is enclosed in the glass tube. Introduction of halogen elements allows for setting the temperature of the filament to a high temperature while suppressing breakage of the filament. The halogen lamp HL thus has properties of having a longer life and being capable of continuously emitting intense light compared with a typical incandescent lamp. That is to say, the halogen lamp HL is a continuous lighting lamp continuously emitting light for at least one second or more. The halogen lamps HL have long lives as they are rod-like lamps, and have excellent radiation efficiency toward the semiconductor wafer W above the halogen lamps HL by being arranged along the horizontal direction.

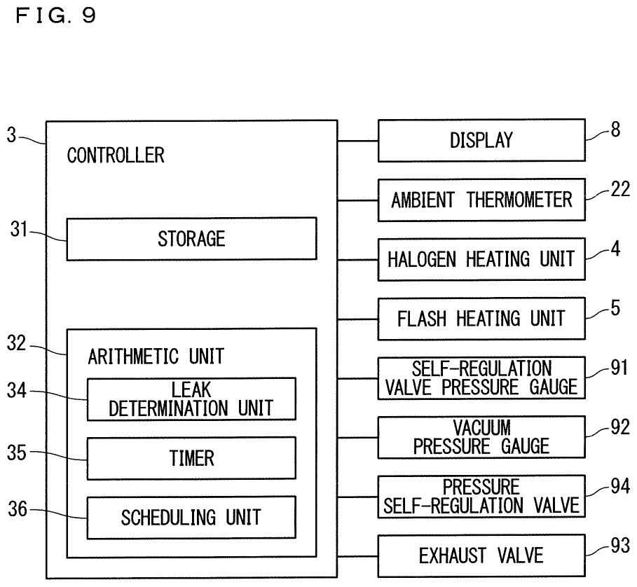

Also in the housing 41 of the halogen heating unit 4, a reflector 43 is disposed below the halogen lamps HL arranged in two tiers (FIG. 1). The reflector 43 reflects light emitted from the plurality of halogen lamps HL toward the thermal processing space 65. The controller 3 controls the above-mentioned various operation mechanisms of the thermal processing apparatus 1. The controller 3 has a similar hardware configuration to a typical computer. That is to say, the controller 3 includes a CPU as a circuit to perform various types of arithmetic processing, ROM as read-only memory to store a basic program, RAM as read/write memory to store various pieces of information, and a magnetic disk to store control software, data, and the like. The CPU of the controller 3 executes a predetermined processing program to proceed with processing performed by the thermal processing apparatus 1. As shown in FIG. 9, the controller 3 includes a storage 31 and an arithmetic unit 32. The storage 31 stores first to fourth thresholds associated with a waiting specified temperature. The first to fourth thresholds will be further described below. The arithmetic unit 32 includes a leak determination unit 34, a timer 35, and a scheduling unit 36. The leak determination unit 34 is a functional processing unit implemented by the CPU of the controller 3 executing the predetermined processing program. The timer 35 has a time measurement function. Details of processing performed by the leak determination unit 34 and the scheduling unit 36 will be further described below. The controller 3 is connected to the display 8, the ambient thermometer 22, the halogen heating unit 4, the flash heating unit 5, the self-regulation valve pressure gauge 91, the vacuum pressure gauge 92, the pressure self-regulation valve 94, the exhaust valve 93, and the like, and controls functions thereof.

In addition to the above-mentioned configuration, the thermal processing apparatus 1 may include various cooling structures to prevent an excessive increase in temperature of the halogen heating unit 4, the flash heating unit 5, and the chamber 6 caused by thermal energy generated by the halogen lamps HL and the flash lamps FL during thermal processing of the semiconductor wafer W. For example, a water-cooled tube (not illustrated) is disposed in a wall body of the chamber 6. The halogen heating unit 4 and the flash heating unit 5 each have an air-cooled structure in which a gas flow is formed to exhaust heat. Air is supplied to a gap between the upper chamber window 63 and the lamp light radiation window 53 to cool the flash heating unit 5 and the upper chamber window 63.

<Procedures of Processing of Semiconductor Wafer W>

Procedures of processing of the semiconductor wafer W performed by the thermal processing apparatus 1 will be described next. The semiconductor wafer W to be processed is herein a semiconductor substrate made of silicon including a high dielectric constant film as a gate insulating film. The high dielectric constant film is formed by being deposited on a front surface of the semiconductor wafer W by a scheme such as atomic layer deposition (ALD) and metal organic chemical vapor deposition (MOCVD), for example. The thermal processing apparatus 1 irradiates the semiconductor wafer W with flashes of light in an ammonia atmosphere for post deposition annealing (PDA) to eliminate defects in the high dielectric constant film after formation. The procedures of processing performed by the thermal processing apparatus 1 described below proceed by the controller 3 controlling each operation mechanism of the thermal processing apparatus 1.

First, the semiconductor wafer W including the high dielectric constant film is transported to the chamber 6 of the thermal processing apparatus 1. When the semiconductor wafer W is transported, the gate valve 185 is opened to open the transport opening 66, and a transport robot outside the apparatus transports the semiconductor wafer W including the high dielectric constant film to the thermal processing space 65 in the chamber 6 through the transport opening 66. In this case, an inside and the outside of the chamber 6 are each at an atmospheric pressure, so that an atmosphere outside the apparatus is entrained in the thermal processing space 65 in the chamber 6 by transport of the semiconductor wafer W. The supply valve 84 may thus be opened to continue supply of the nitrogen gas from the processing gas supply source (a gas supply unit) 85 into the chamber 6 to flow out the nitrogen gas from the transport opening 66 to thereby minimize a flow of the atmosphere outside the apparatus into the chamber 6. Furthermore, when the gate valve 185 is opened, exhaustion from the chamber 6 is preferably stopped by closing the exhaust valve 93. The nitrogen gas supplied into the chamber 6 thus flows out only from the transport opening 66, so that the flow of the outside atmosphere can more effectively be prevented.

The semiconductor wafer W transported by the transport robot is moved to a position directly above the holding unit 7, and is stopped. The pair of transfer arms 11 of the transfer mechanism 10 horizontally moves from the withdrawal position to the transfer operation position and moves upward, so that the lift pins 12 pass through the through holes 79 to protrude from the upper surface of the holding plate 75 of the susceptor 74 and receive the semiconductor wafer W. In this case, the lift pins 12 are moved above the upper ends of the substrate support pins 77.

After the semiconductor wafer W is mounted on the lift pins 12, the transport robot leaves the thermal processing space 65, and the transport opening 66 is closed by the gate valve 185. The pair of transfer arms 11 moves downward, so that the semiconductor wafer W is transferred from the transfer mechanism 10 to the susceptor 74 of the holding unit 7 and is held in the horizontal orientation from below. The semiconductor wafer W is held by the susceptor 74 while being supported by the plurality of substrate support pins 77 arranged to stand on the holding plate 75. The semiconductor wafer W is held by the susceptor 74 with the front surface on which the high dielectric constant film has been formed facing upward. There is a predetermined distance between a back surface (a main surface opposite the front surface) of the semiconductor wafer W supported by the plurality of substrate support pins 77 and the holding surface 75a of the holding plate 75. The pair of transfer arms 11 having moved downward to a position below the susceptor 74 is withdrawn by the horizontal movement mechanism 13 to the withdrawal position, that is, to the inside of the recess 62.

After the semiconductor wafer W is housed in the chamber 6, and the transport opening 66 is closed by the gate valve 185, the pressure in the chamber 6 is reduced to a pressure lower than the atmospheric pressure. After the semiconductor wafer W is first transported into the chamber 6 at an atmospheric pressure Ps (=approximately 101325 Pa), the transport opening 66 is closed by the gate valve 185 to cause the thermal processing space 65 in the chamber 6 to be the enclosed space. In this state, the controller 3 activates the vacuum pump (a gas discharge unit) 95 and opens the exhaust valve 93, so that the atmosphere in the chamber 6 is withdrawn through the gas exhaust hole 86 and is evacuated to the gas exhaust tubes 88. The controller 3 also closes the supply valve 84 to supply gas. Gas is thus exhausted without supplying a gas into the chamber 6, so that a pressure in the thermal processing space 65 in the chamber 6 is reduced.

The controller 3 also controls the pressure self-regulation valve 94 to exhaust gas to a pressure P1 (e.g., approximately 20000 Pa) at a relatively small exhaust flow rate, and then increases the exhaust flow rate. That is to say, after gas is exhausted at a small exhaust flow rate at an early stage of pressure reduction, the exhaust flow rate is switched to a larger exhaust flow rate for exhaustion. If gas is rapidly exhausted at a large exhaust flow rate from the start of pressure reduction, an air current in the chamber 6 greatly changes, and particles having been attached to a structure (e.g., the lower chamber window 64) of the chamber 6 might curl up and be attached to the semiconductor wafer W again to contaminate the semiconductor wafer W. If gas is gently exhausted at a small exhaust flow rate at the early stage of pressure reduction, and then the exhaust flow rate is switched to the larger exhaust flow rate for exhaustion, such a curl up of the particles in the chamber 6 can be prevented.

The pressure (a degree of vacuum) in the chamber 6 reaches a pressure P2 in due course. The pressure P2 is approximately 100 Pa, for example. When the pressure in the chamber 6 reaches the pressure P2, the supply valve 84 to supply gas is opened, and a mixture of ammonia and the nitrogen gas as a diluent gas is supplied from the processing gas supply source 85 to the thermal processing space 65 in the chamber 6. As a result, the ammonia atmosphere is formed around the semiconductor wafer W held by the holding unit 7 in the chamber 6. An ammonia concentration (i.e., a mixing ratio of ammonia to the nitrogen gas) in the ammonia atmosphere is not particularly limited and can have an appropriate value, and is only required to be 10 vol. % or less (approximately 2.5 vol. % in the present embodiment), for example.

By supplying the mixture into the chamber 6, the pressure in the chamber 6 increases from the pressure P2 and is returned to a pressure P3. The pressure P3 as a processing pressure of the semiconductor wafer W is higher than the pressure P2, lower than the atmospheric pressure Ps, and is approximately 5000 Pa, for example. The pressure in the chamber 6 is once reduced to the pressure P2 and is returned to the pressure P3, so that an oxygen concentration in the ammonia atmosphere in the chamber 6 after pressure return can be approximately 200 ppb or less.

After the pressure in the chamber 6 is returned to the pressure P3, a supply flow rate of the mixture of ammonia and nitrogen to the chamber 6 and the exhaust flow rate from the chamber 6 are caused to be generally equal to each other to maintain the pressure in the chamber 6 to the pressure P3. When the pressure in the chamber 6 is maintained to the pressure P3 lower than the atmospheric pressure, the controller 3 provides the pressure self-regulation valve 94 with the pressure P3 as the set value (indicated value) of the pressure in the chamber 6. The pressure self-regulation valve 94 performs feedback control of the opening so that the pressure in the chamber 6 has the above-mentioned set value (pressure P3) based on the result of measurement of the pressure in the chamber 6 by the self-regulation valve pressure gauge 91.

Furthermore, after the pressure in the chamber 6 is returned to the pressure P3, the halogen lamps HL of the halogen heating unit 4 are simultaneously turned on to start preheating (assist heating) of the semiconductor wafer W. Halogen light emitted from the halogen lamps HL is transmitted through the lower chamber window 64 and the susceptor 74 each made of quartz, and is applied to the back surface of the semiconductor wafer W. By being irradiated with light from the halogen lamps HL, the semiconductor wafer W is preheated to have an increased temperature. The transfer arms 11 of the transfer mechanism 10 are withdrawn to the inside of the recess 62, and thus do not interfere with heating by the halogen lamps HL.

When the halogen lamps HL perform preheating, the temperature of the semiconductor wafer W is measured by the radiation thermometer 20. That is to say, the radiation thermometer 20 receives, through the transparent window 21, infrared light radiated from the lower surface of the semiconductor wafer W held by the susceptor 74 through the opening 78, and measures the wafer temperature being increased. The measured temperature of the semiconductor wafer W is transmitted to the controller 3. The controller 3 controls output of the halogen lamps HL while monitoring the temperature of the semiconductor wafer W increased by irradiation with light from the halogen lamps HL to determine whether it has reached a predetermined preheat temperature Tx. That is to say, the controller 3 performs feedback control of output of the halogen lamps HL based on a value measured by the radiation thermometer 20 so that the temperature of the semiconductor wafer W becomes the preheat temperature Tx. The preheat temperature Tx is 300° C. or more and 600° C. or less and is 450° C. in the present embodiment.

After the temperature of the semiconductor wafer W reaches the preheat temperature Tx, the controller 3 maintains the semiconductor wafer W at the preheat temperature Tx for a while. Specifically, at a point in time when the temperature of the semiconductor wafer W measured by the radiation thermometer 20 reaches the preheat temperature Tx, the controller 3 adjusts output of the halogen lamps HL to maintain the semiconductor wafer W substantially at the preheat temperature Tx.

Such preheating by the halogen lamps HL allows for a uniform increase in temperature of the semiconductor wafer W as a whole to the preheat temperature Tx. At a stage of preheating by the halogen lamps HL, the temperature at the periphery of the semiconductor wafer W where heat is more likely to be dissipated tends to be lower than the temperature in the central portion of the semiconductor wafer W, but the halogen lamps HL of the halogen heating unit 4 are denser in the region opposing the periphery of the semiconductor wafer W than in the region opposing the central portion of the semiconductor wafer W. The periphery of the semiconductor wafer W where heat is likely to be dissipated is thus irradiated with a greater amount of light to make in-plane temperature distribution of the semiconductor wafer W at the preheating stage uniform. The pressure in the chamber 6 during preheating is maintained to the pressure P3.

Next, at time t6 when a predetermined time has elapsed since the temperature of the semiconductor wafer W reaching the preheat temperature Tx, the flash lamps FL of the flash heating unit 5 irradiate the front surface of the semiconductor wafer W held by the susceptor 74 with flashes of light. In this case, some flashes of light radiated from the flash lamps FL are directly directed toward the inside of the chamber 6, and other flashes of light radiated from the flash lamps FL are once reflected by the reflector 52 and then directed toward the inside of the chamber 6, so that the semiconductor wafer W is flash heated by irradiation with these flashes of light (a flash heating step).

Flash heating is performed by irradiation with flashes of light from the flash lamps FL, so that the temperature of the front surface of the semiconductor wafer W can be increased in a short time. That is to say, flashes of light emitted from the flash lamps FL are intense flashes of light having an extremely short irradiation time of approximately 0.1 ms or more and 100 ms or less obtained by converting electrostatic energy stored in advance in the capacitor into an extremely short light pulse. By irradiating the front surface of the semiconductor wafer W on which the high dielectric constant film has been formed with flashes of light from the flash lamps FL, the temperature of the front surface of the semiconductor wafer W including the high dielectric constant film is increased to a processing temperature Ty to perform post deposition annealing. The processing temperature Ty as a maximum temperature (peak temperature) that the temperature of the front surface of the semiconductor wafer W reaches due to irradiation with flashes of light is 600° C. or more and 1200° C. or less and is 1000° C. in the present embodiment.

When the temperature of the front surface of the semiconductor wafer W is increased to the processing temperature Ty in the ammonia atmosphere to perform post deposition annealing, nitridation of the high dielectric constant film is facilitated, and defects, such as point defects, in the high dielectric constant film are eliminated. The irradiation time of the flash lamps FL is a short time of approximately 0.1 ms or more and 100 ms or less, so that a time required to increase the temperature of the front surface of the semiconductor wafer W from the preheat temperature Tx to the processing temperature Ty is an extremely short time of less than one second. The temperature of the front surface of the semiconductor wafer W after irradiation with flashes of light immediately rapidly decreases from the processing temperature Ty.

When a predetermined time has elapsed since the end of flash heating, the controller 3 closes the supply valve 84 to reduce the pressure in the chamber 6 to the pressure P2 again. Harmful ammonia can thereby be discharged from the thermal processing space 65 in the chamber 6. Then, when the pressure in the chamber 6 reaches the pressure P2, the controller 3 closes the exhaust valve 93 and opens the supply valve 84 to supply the nitrogen gas as the inert gas from the processing gas supply source 85 into the chamber 6 to return the pressure in the chamber 6 to the atmospheric pressure Ps. The halogen lamps HL are turned off, so that the temperature of the semiconductor wafer W is decreased from the preheat temperature Tx. The temperature of the semiconductor wafer W being decreased is measured by the radiation thermometer 20, and a result of measurement is transmitted to the controller 3. The controller 3 monitors the temperature of the semiconductor wafer W to determine whether it has been decreased to a predetermined temperature based on the result of measurement. After the atmosphere in the chamber 6 is replaced with a nitrogen atmosphere to return the pressure in the chamber 6 to the atmospheric pressure Ps and to decrease the temperature of the semiconductor wafer W to or below a predetermined temperature, the pair of transfer arms 11 of the transfer mechanism 10 horizontally moves from the withdrawal position to the transfer operation position and moves upward, so that the lift pins 12 protrude from the upper surface of the susceptor 74 and receive the semiconductor wafer W after thermal processing from the susceptor 74. Then, the transport opening 66 having been closed by the gate valve 185 is opened, and the semiconductor wafer W mounted on the lift pins 12 are transported by the transport robot outside the apparatus to complete heating of the semiconductor wafer W in the thermal processing apparatus 1.

<Leak Determination Processing>

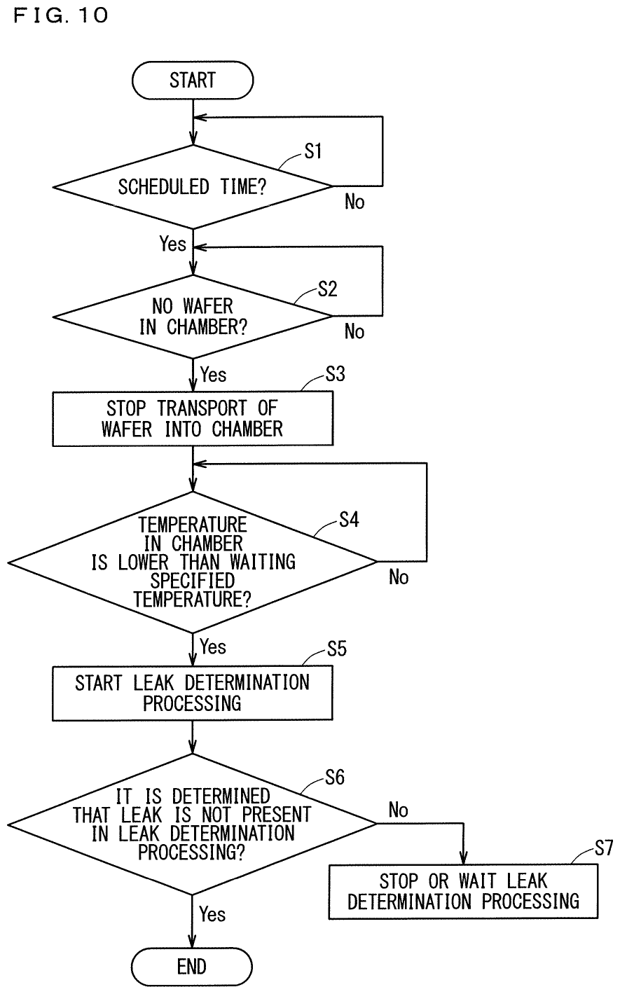

FIG. 9 is a block diagram showing a relationship with each unit to perform leak determination processing in the present embodiment, and FIG. 10 is a flowchart showing a flow of the leak determination processing in the present embodiment.

In the thermal processing apparatus 1 in the present embodiment, once a leak occurs in the chamber 6, the pressure in the chamber 6 cannot be reduced to a predetermined pressure, and harmful ammonia might leak. It is thus important to detect the presence or absence of the leak in the chamber 6. The controller 3 to perform control of the thermal processing apparatus 1 in the present embodiment includes the storage 31 and the arithmetic unit 32. A relationship between the waiting specified temperature and the first to fourth thresholds is stored in the storage 31. The waiting specified temperature is a room temperature in the present embodiment.

The arithmetic unit 32 includes the leak determination unit 34, the timer 35, and the scheduling unit 36. The leak determination unit 34 performs the leak determination processing of the chamber 6 according to procedures described below (a leak determination step). The scheduling unit 36 performs scheduling by setting time at which the leak determination processing is performed (a scheduling step). For example, an interval of scheduling is selected from “not performed”, “once a day”, “once a week”, and “once a month” and is set. An option other than the above-mentioned options may be set. The leak determination processing may be performed at any timing of an operator.

To perform the leak determination processing in the present embodiment, whether time has reached the time at which the leak determination processing is performed preset by the scheduling unit 36 is determined first (step S1). When it is determined that the time has reached the time set by the scheduling unit 36, processing proceeds to the next step. On the other hand, when it is not determined that the time has reached the time set by the scheduling unit 36, the leak determination processing is not performed. The leak determination processing is performed after it is determined that the time has reached the set time.

When it is determined that the time has reached the time set by the scheduling unit 36 in step S1, whether the semiconductor wafer W is being heated in the chamber 6 at the point in time is determined (step S2). Even if the time has reached the time set by the scheduling unit 36, the leak determination processing is not performed when the semiconductor wafer W is being heated in the chamber 6. In this case, the leak determination processing is started after heating of the semiconductor wafer W ends and the semiconductor wafer W is transported from the chamber 6. The leak determination processing of the chamber 6 is thus always performed with no semiconductor wafer W in the chamber 6. The presence or absence of the leak in the chamber 6 can thus be detected with accuracy without being affected by the semiconductor wafer W. If the leak determination processing is performed with the semiconductor wafer W being housed in the chamber 6, the semiconductor wafer W can be a defective product. A risk of production of a defective semiconductor wafer W can be reduced by performing setting so that the leak determination processing is performed after waiting until the semiconductor wafer W is transported from the chamber 6 as described above.

When it is determined that the semiconductor wafer W is not being heated in the chamber 6 in step S2, transport of a new semiconductor wafer W into the chamber 6 is stopped (step S3). The new semiconductor wafer W is thus not heated in the chamber 6 until the next leak determination processing is performed.

When transport of the new semiconductor wafer W into the chamber 6 is stopped in step S3, waiting is continued until an ambient temperature in the chamber 6 decreases to a predetermined waiting specified temperature (step S4). The ambient temperature is measured by the ambient thermometer 22, for example. The predetermined waiting specified temperature is the room temperature in the present embodiment. The room temperature refers to a temperature of 20° C.±15° C. (i.e., 5° C. to 35° C.) as defined in JIS Z 8703. Waiting is continued until the ambient temperature measured by the ambient thermometer 22 reaches the predetermined waiting specified temperature (room temperature). When the ambient temperature reaches the waiting specified temperature in step S4, the leak determination processing is started (step S5). The presence or absence of the leak is determined in the leak determination processing (step S6). When it is determined that “the leak is not present” in the leak determination processing, a series of processes ends. On the other hand, when it is determined that “there is a possibility of the leak” or “the leak is present” in the leak determination processing, the leak determination processing is stopped or waited (step S7). In the present embodiment, the leak determination processing includes first determination processing and second determination processing.

<First Determination Step>

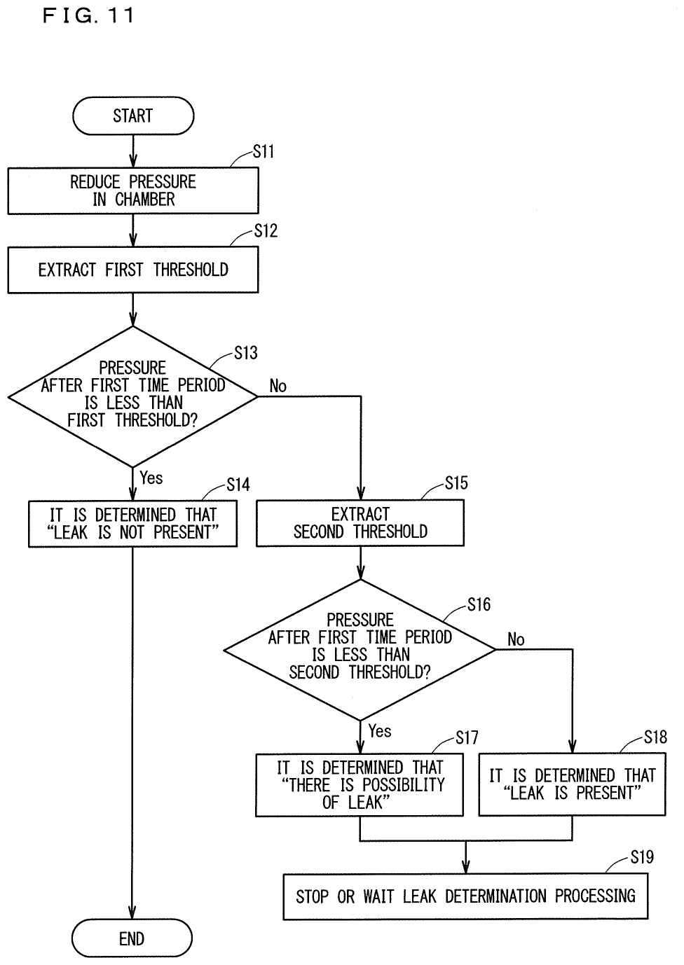

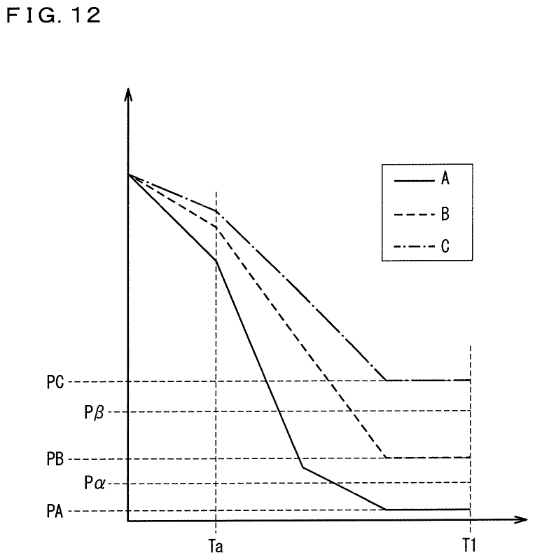

Procedures of processing in a first determination step are described herein. FIG. 11 is a flowchart showing a flow of the first determination processing in the present embodiment. FIG. 12 is a diagram showing a pressure change in the chamber 6 in first determination at the room temperature. In FIG. 12, a vertical axis represents the pressure in the chamber 6, and a horizontal axis represents time. T1 is a first time period, Pα is a first threshold, and Pβ is a second threshold.

In the thermal processing apparatus 1, the semiconductor wafer W is transported from the chamber 6 (a transport step), and the transport opening 66 is closed by the gate valve 185. The transport opening 66 is closed by the gate valve 185 to cause the thermal processing space 65 in the chamber 6 to be the enclosed space. The pressure in the chamber 6 is reduced in this state (step S11). The pressure in the chamber 6 is reduced by discharging gas from the chamber 6 while stopping supply of gas into the chamber 6. Specifically, the controller 3 closes the supply valve 84 and opens the exhaust valve 93 while activating the vacuum pump 95. An elapsed time since the start of reduction in pressure in the chamber 6 is measured by the timer 35 (see FIG. 9).

A speed of a flow of a gas into and out of the chamber 6 is considered to vary depending on a temperature. The leak determination processing is thus preferably performed under substantially the same temperature condition. In the present embodiment, a change over time of the pressure in the chamber 6 at the waiting specified temperature (room temperature in the present embodiment) when the pressure is reduced for a predetermined time period (the first time period T1) and the presence or absence of the leak are associated with each other in advance, and a relationship between them is stored in the storage 31.

Next, the first threshold (Pα) is extracted from the storage 31 (step S12). The extracted first threshold (Pα) is used for calculation performed by the arithmetic unit 32. The leak determination unit 34 of the arithmetic unit 32 compares a pressure after the first time period T1 and the first threshold (Pα). The first time period T1 for leak determination is set in advance by the controller 3 (e.g., T1=1800 seconds). The setting may be changeable by the operator. The pressure in the chamber 6 is measured by the vacuum pressure gauge 92 (see FIG. 8). In an example of FIG. 12 described above, the pressure is reduced in two stages by switching the exhaust flow rate, and reduction in pressure in the chamber 6 in a second stage is started at time Ta. In the first determination, the presence or absence of the leak is determined by whether the pressure in the chamber 6 is reduced to a pressure less than the first threshold (Pα) (or the second threshold (Pβ)) in the first time period T1. More specifically, the leak determination unit 34 determines whether the pressure after the first time period T1 is less than the first threshold (Pα) (step S13). When the pressure in the chamber 6 after the first time period T1 is less than the first threshold (Pα) in determination in step S13, it is determined that “the leak is not present” (step S14). For example, a solid line A shown in FIG. 12 decreases to a pressure PA in the first time period T1. That is to say, the pressure becomes less than the first threshold (Pα) (e.g., Pα=100 Pa) in the first time period T1, and thus, when the pressure transitions as in the solid line A, it is determined that “the leak is not present” in the chamber 6, and the first determination ends.

On the other hand, when the pressure after the first time period T1 is equal to or greater than the first threshold (Pα) in determination in step S13, the second threshold (Pβ) is extracted from the storage 31 (step S15). The extracted second threshold (Pβ) is used for calculation performed by the arithmetic unit 32. The leak determination unit 34 of the arithmetic unit 32 compares the pressure after the first time period T1 and the second threshold (Pβ). The leak determination unit 34 determines whether the pressure after the first time period T1 is less than the second threshold (Pβ) (step S16).

When the pressure after the first time period T1 is less than the second threshold (Pβ) in determination in step S16, it is determined that “there is a possibility of the leak” (step S17). For example, a dotted line B shown in FIG. 12 decreases to a pressure PB in the first time period T1. The pressure PB is equal to or greater than the first threshold (Pα) and is less than the second threshold (Pβ) (e.g., Pβ=500 Pa). That is to say, since the pressure becomes equal to or greater than the first threshold (Pα) and becomes less than the second threshold (Pβ) in the first time period T1, it is determined that “there is a possibility of the leak” in the chamber 6. In this case, the display 8 (see FIG. 9) may display a warning message indicating that “there is a possibility of the leak”, for example.

On the other hand, when the pressure after the first time period T1 is equal to or greater than the second threshold (Pβ) in determination in step S16, it is determined that “the leak is present” (step S18). For example, an alternate long and short dashed line C shown in FIG. 12 decreases only to a pressure PC in the first time period T1. The pressure PC is equal to or greater than the second threshold (Pβ). That is to say, since the pressure becomes equal to or greater than the second threshold (Pβ) in the first time period T1, it is determined that “the leak is present” in the chamber 6. In this case, the display 8 (see FIG. 9) may display an alarm message indicating that “the leak is present”, for example.

The leak determination processing is waited (step S19) when it is determined that “there is a possibility of the leak” in step S17 described above, and the leak determination processing is stopped (step S19) when it is determined that “the leak is present” in step S18 described above.

<Second Determination Step>

In the present embodiment, when it is determined that the leak is not present in the chamber 6 in the above-mentioned first determination, the second determination processing is started.

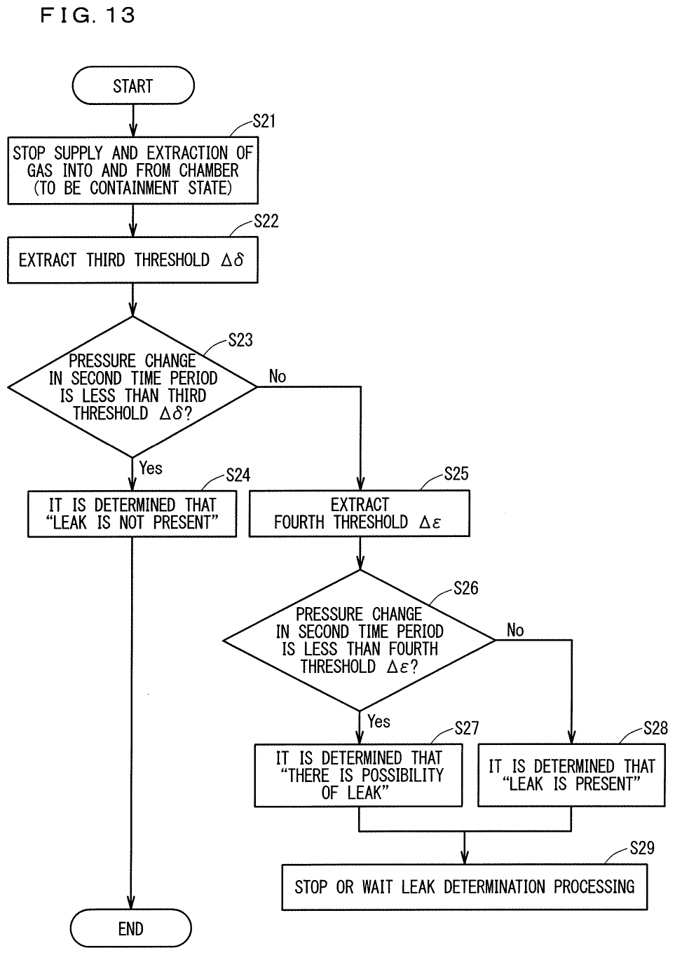

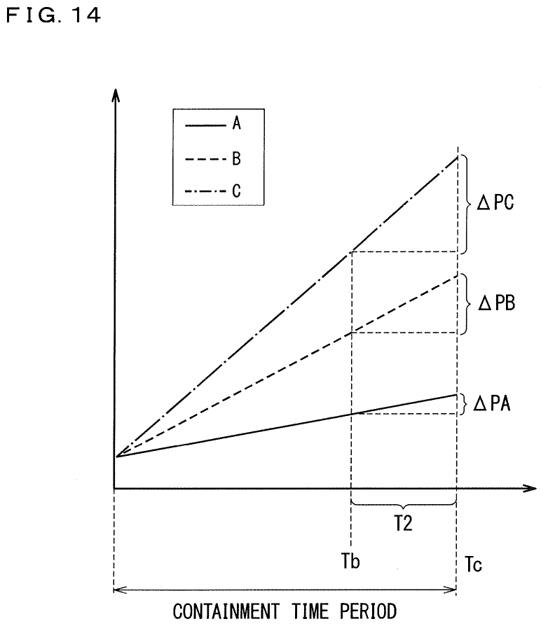

Procedures of processing in a second determination step are described herein. FIG. 13 is a flowchart showing a flow of the second determination processing in the present embodiment. FIG. 14 is a diagram showing a pressure change in the chamber 6 in second determination at the room temperature. In FIG. 14, a vertical axis represents the pressure in the chamber 6, and a horizontal axis represents time. T2 is a second time period, Tb is a start of the second time period T2, and Tc is an end of the second time period T2. ΔP is a difference between a pressure at the start Tb and a pressure at the end Tc of the second time period T2.

In the thermal processing apparatus 1, a closed state of the transport opening 66 is maintained by the gate valve 185 after the first determination. The thermal processing space 65 in the chamber 6 is thus the enclosed space. In this state, discharge of gas from the chamber 6 is stopped while supply of gas into the chamber 6 is stopped (step S21). The pressure in the chamber 6 is reduced compared with a pressure of external air due to the first determination processing, and the chamber 6 is maintained at the reduced pressure. Specifically, the controller 3 closes the supply valve 84 and closes the exhaust valve 93. This state is referred to as a containment state, and a time period during which the supply valve 84 and the exhaust valve 93 are closed is referred to as a containment time period (see FIG. 14). An elapsed time (the second time period T2) since the start of the second determination is measured by the timer 35 (see FIG. 9).

In second leak determination, the presence or absence of the leak is determined by whether the amount of the leak from the chamber 6 in the second time period T2 is less than a third threshold (or a fourth threshold). In the present embodiment, the amount of a pressure change in the chamber 6 in a predetermined time period is used as the amount of the leak. In the present embodiment, the presence or absence of the leak is determined by the amount of the pressure change in the chamber 6 in the second time period T2 after waiting is continued for a given time period (e.g., 1200 seconds) from the start of maintaining the chamber 6 at the reduced pressure. That is to say, the start Tb of the second time period T2 is later than a start of the containment time period. An end of the containment time period and the end Tc of the second time period coincide with each other.

The start Tb of the second time period T2 is set to be later than the start of the containment time period for the following reason. For example, a timing of closing sometimes varies between the supply valve 84 and the exhaust valve 93 due to a difference in models thereof. If the timing of closing varies between the supply valve 84 and the exhaust valve 93, determination of the presence or absence of the leak is likely to be affected by a pressure change caused by a gas leaked from the supply valve 84 or the exhaust valve 93 itself. The start Tb of the second time period T2 is thus set to be later than the start of the containment time period to reduce the influence of the variation of the timing of closing between the supply valve 84 and the exhaust valve 93 due to the difference in models thereof. The leak determination processing can thus be performed after stopping of supply and discharge of gas is stabilized. The presence or absence of the leak in the chamber 6 can thus be detected with accuracy.

The speed of the flow of the gas into and out of the chamber 6 is considered to vary depending on the temperature as in the first determination processing, and second leak determination processing is also preferably performed under substantially the same temperature condition. In the present embodiment, the amount of the pressure change (the amount of the leak) in the chamber 6 at the waiting specified temperature (room temperature in the present embodiment) when the chamber 6 is maintained at the reduced pressure for the predetermined time period (the second time period T2) and the presence or absence of the leak are associated with each other in advance, and a relationship between them is stored in the storage 31.

Next, the third threshold (Δδ) is extracted from the storage 31 (step S22). The extracted third threshold (Δδ) is used for calculation performed by the arithmetic unit 32. The leak determination unit 34 of the arithmetic unit 32 compares a pressure after the second time period T2 and the third threshold (Δδ). The second time period T2 for leak determination is set in advance by the controller 3 (e.g., T2=600 seconds). The setting may be changeable by the operator. The pressure in the chamber 6 is measured by the vacuum pressure gauge 92 (see FIG. 8). The presence or absence of the leak is determined by whether the pressure change in the chamber 6 in the second time period T2 is less than the third threshold (Δδ) (or the fourth threshold (Δε)). Specifically, the leak determination unit 34 determines whether the pressure change in the second time period T2 (the difference ΔP between the pressure at the start Tb and the pressure at the end Tc of the second time period T2) is less than the third threshold (Δδ) (step S23). When the pressure change ΔP in the chamber 6 in the second time period T2 is less than the third threshold (Δδ) in determination in step S23, it is determined that “the leak is not present” (step S24). For example, a solid line A shown in FIG. 14 exhibits a pressure change ΔPA (<Δδ) (e.g., ΔPA=3 Pa and Δδ=4.8 Pa) in the second time period T2. That is to say, the pressure change in the second time period T2 is less than the third threshold (Δδ), and thus, when the pressure transitions as in the solid line A, it is determined that “the leak is not present” in the chamber 6, and the second determination ends.

On the other hand, when the pressure change ΔP in the second time period T2 is equal to or greater than the third threshold (Δδ) in determination in step S23, the fourth threshold (Δε) is extracted from the storage 31 (step S25). The extracted fourth threshold (Δε) is used for calculation performed by the arithmetic unit 32. The leak determination unit 34 of the arithmetic unit 32 compares the pressure change ΔP in the second time period T2 and the fourth threshold (Δε). The leak determination unit 34 determines whether the pressure change ΔP in the second time period T2 is less than the fourth threshold (Δε) (step S26).

When the pressure change ΔP in the second time period T2 is less than the fourth threshold (Δε) in determination in step S26, it is determined that “there is a possibility of the leak” (step S27). For example, a dotted line B shown in FIG. 14 exhibits a pressure change ΔPB (<Δε) (e.g., ΔPB=13 Pa and Δε=24 Pa) in the second time period T2. The pressure change ΔPB is equal to or greater than the third threshold (Δδ) and is less than the fourth threshold (Δε). That is to say, since the pressure change ΔPB in the second time period T2 is equal to or greater than the third threshold (Δδ) and is less than the fourth threshold (Δε), it is determined that “there is a possibility of the leak” in the chamber 6. In this case, the display 8 (see FIG. 9) may display the warning message indicating that “there is a possibility of the leak”, for example.

On the other hand, when the pressure change in the second time period T2 is equal to or greater than the fourth threshold (Δε) in determination in step S26, it is determined that “the leak is present” (step S28). For example, an alternate long and short dashed line C shown in FIG. 14 exhibits a pressure change ΔPC (>Δε) (e.g., ΔPC=27 Pa) in the second time period T2. The pressure change ΔPC is equal to or greater than the fourth threshold (Δε). That is to say, since the pressure change ΔPC in the second time period T2 is equal to or greater than the fourth threshold (Δε), it is determined that “the leak is present” in the chamber 6. In this case, the display 8 (see FIG. 9) may display the alarm message indicating that “the leak is present”, for example.

The leak determination processing is waited (step S29) when it is determined that “there is a possibility of the leak” in step S27 described above, and the leak determination processing is stopped (step S29) when it is determined that “the leak is present” in step S28 described above.

When it is determined that “there is a possibility of the leak” or “the leak is present” in the leak determination processing described above, processing may transition to maintenance processing, such as leak portion check processing and leak portion repair/replacement processing.

### Second Embodiment

A second embodiment of the present invention will be described next. A configuration of the thermal processing apparatus 1 in the second embodiment is similar to that in the first embodiment. Procedures of processing of the semiconductor wafer W in the thermal processing apparatus 1 in the second embodiment is also similar to those in the first embodiment. The second embodiment differs from the first embodiment in the leak determination processing of the chamber 6.

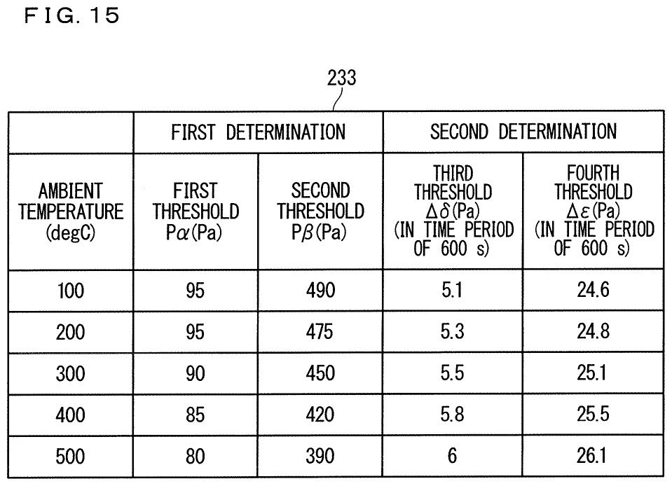

The second embodiment differs from the first embodiment in that the storage 31 in FIG. 9 stores a correspondence table 233 (see FIG. 15). FIG. 15 is a diagram showing the correspondence table 233 in which the waiting specified temperature and the first to fourth thresholds are associated with each other.

In the second embodiment, the predetermined waiting specified temperature in step S4 in FIG. 10 is higher than the room temperature. The correspondence table 233 is a table in which the waiting specified temperature, the first threshold, the second threshold, the third threshold, and the fourth threshold in the chamber 6 are associated with one another. The correspondence table 233 is created in advance before the first determination and the second determination. The correspondence table 233 is created in a table creation step of creating the correspondence table in which the waiting specified temperature, the first threshold, the second threshold, the third threshold, and the fourth threshold are associated with one another. The created correspondence table 233 is stored in the storage 31. The correspondence table 233 may be created based on experimental data obtained so far and the like.

As shown in FIG. 15, first thresholds, second thresholds, third thresholds, and fourth thresholds at temperatures of 100° C., 200° C., 300° C., 400° C., and 500° C. as predetermined waiting specified temperatures are associated in the correspondence table 233, for example. The leak determination processing can thus be performed without waiting for the decrease of the ambient temperature in the chamber 6 to the room temperature. A time required for the leak determination processing can thus be reduced. A response to various ambient temperatures is possible, so that accuracy of the leak determination processing is improved. A condition for the leak determination, however, is required to be changed from that in the first embodiment in response to various ambient temperatures. It is considered that, as the temperature increases, the gas density decreases, and an exhaust efficiency increases. Pressures as the thresholds in the first determination (the first threshold (Pα) and the second threshold (Pβ)) are thus set to decrease with increasing waiting specified temperature. Values of the pressure change as the thresholds in the second determination (the third threshold (Δδ) and the fourth threshold (Δε)) are set to increase with increasing waiting specified temperature.

For example, when the ambient temperature increases to a temperature slightly higher than 300° C. due to immediately preceding heating of the semiconductor wafer W, the leak determination processing can be performed using the first threshold, the second threshold, the third threshold, and the fourth threshold corresponding to the most recent temperature of 300° C. Specifically, when the ambient temperature reaches the waiting specified temperature (300° C.) in step S4 in FIG. 10, the leak determination processing is started (step S5). The waiting specified temperature is preferably a temperature lower than the ambient temperature immediately before the start of the leak determination processing. This is because the interior of the chamber 6 is required to be reheated when the waiting specified temperature is a temperature higher than the ambient temperature immediately before the start of the leak determination processing. The most recent temperature is preferably selected as the waiting specified temperature from among a plurality of temperatures stored in the correspondence table 233. This is because the most recent temperature allows for reduction in waiting time until the decrease to the waiting specified temperature.

In the first determination in the second embodiment, the pressure in the chamber 6 is reduced (step S11) with the thermal processing space 65 in the chamber 6 being the enclosed space as in the first embodiment. Next, the first threshold (Pα) corresponding to the waiting specified temperature as specified is extracted from the correspondence table 233 (step S12). As shown in FIG. 15, 90 Pa is extracted from the correspondence table 233 as the first threshold (Pα) when the waiting specified temperature is 300° C., for example. A case where the waiting specified temperature is 300° C. will be described below as one example of the flow.

Next, the leak determination unit 34 determines whether the pressure after the first time period T1 is less than the first threshold (90 Pa) (step S13). When the pressure in the chamber 6 becomes less than the first threshold (90 Pa) in the first time period T1, it is determined that “the leak is not present” in the chamber 6 (step S14). The first determination then ends.

On the other hand, when the pressure after the first time period T1 is equal to or greater than the first threshold (90 Pa) in determination in step S13, the second threshold (Pβ) corresponding to the waiting specified temperature as specified is extracted from the correspondence table 233 next. As shown in FIG. 15, 450 Pa is extracted from the correspondence table 233 as the second threshold (Pβ) when the waiting specified temperature is 300° C. (step S15). The leak determination unit 34 determines whether the pressure after the first time period T1 is less than the second threshold (450 Pa) (step S16).

When the pressure after the first time period T1 is less than the second threshold (450 Pa) in determination in step S16, it is determined that “there is a possibility of the leak” (step S17). In this case, the display 8 (see FIG. 9) may display the warning message indicating that “there is a possibility of the leak”, for example.

On the other hand, when the pressure after the first time period T1 is equal to or greater than the second threshold (450 Pa) in determination in step S16, it is determined that “the leak is present” (step S18). In this case, the display 8 (see FIG. 9) displays the alarm message indicating that “the leak is present”, for example.

The leak determination processing is waited (step S19) when it is determined that “there is a possibility of the leak” in step S17 described above, and the leak determination processing is stopped (step S19) when it is determined that “the leak is present” in step S18 described above as in the first embodiment.

The second determination is made when it is determined that “the leak is not present” in the first determination described above.

In the second determination in the present embodiment, discharge of gas from the chamber 6 is stopped while supply of gas into the chamber 6 is stopped (step S21) with the thermal processing space 65 in the chamber 6 being the enclosed space as in the first embodiment.

Next, also in the second determination, the third threshold (Δδ) corresponding to the waiting specified temperature is extracted from the correspondence table 233 (step S22). As shown in FIG. 15, 5.5 Pa is extracted from the correspondence table 233 as the third threshold Δδ when the waiting specified temperature is 300° C., for example. The case where the waiting specified temperature is 300° C. will be described below as one example of the flow as in the first determination in the present embodiment.

The leak determination unit 34 determines whether the pressure change ΔP in the second time period T2 (600 s) is less than the third threshold (5.5 Pa) (step S23). When the pressure change ΔP in the chamber 6 in the second time period T2 is less than the third threshold (5.5 Pa) in determination in step S23, it is determined that “the leak is not present” (step S24). The second leak determination then ends.

On the other hand, when the pressure change ΔP in the second time period T2 is equal to or greater than the third threshold (5.5 Pa) in determination in step S23, the fourth threshold (Δε) is extracted from the correspondence table 233 (step S25). As shown in FIG. 15, 25.1 Pa is extracted from the correspondence table 233 as the fourth threshold Δε when the waiting specified temperature is 300° C., for example. The leak determination unit 34 determines whether the pressure change ΔP in the second time period T2 is less than the fourth threshold (25.1 Pa) (step S26).

When the pressure change ΔP in the second time period T2 is less than the fourth threshold (25.1 Pa) in determination in step S26, it is determined that “there is a possibility of the leak” (step S27). In this case, the display 8 (see FIG. 9) may display the warning message indicating that “there is a possibility of the leak”, for example.

On the other hand, when the pressure change in the second time period T2 is equal to or greater than the fourth threshold (25.1 Pa) in determination in step S26, it is determined that “the leak is present” (step S28). In this case, the display 8 (see FIG. 9) may display the alarm message indicating that “the leak is present”, for example.

The leak determination processing is waited (step S29) when it is determined that “there is a possibility of the leak” in step S27 described above, and the leak determination processing is stopped (step S29) when it is determined that “the leak is present” in step S28 described above.

According to the leak determination processing in the present embodiment as described above, the leak determination processing is performed using the first threshold (Pα), the second threshold (Pβ), the third threshold (Δδ), or the fourth threshold (Δε) corresponding to the temperature at which the leak determination processing is performed. The presence or absence of the leak in the chamber 6 can thus be detected with accuracy.

<Modifications>

While the embodiments of the present invention have been described above, various changes other than those described above can be made without departing from the spirit of the present invention. For example, each threshold set for leak determination in each of the above-mentioned embodiments can have an appropriate value according to a configuration and specifications of the apparatus.

While the ammonia atmosphere is formed in the chamber 6 in each of the above-mentioned embodiments, technology according to the present invention is applicable to a case where an atmosphere of a reactive gas, such as ammonia, is not formed in the chamber 6 (e.g., a case where the nitrogen atmosphere is formed in the chamber 6). Technology according to the present invention, however, is more suitably applicable to a case where an atmosphere of a reactive gas that is harmful when leaking is formed in the chamber 6.

While the amount of the pressure change in the chamber 6 is used for the second determination in the above-mentioned embodiments, the amount of gas volume (e.g., in Pa·m³/sec) having been moved in a unit of time may be used. This case is useful in terms of ease of representation of a small value.

While the leak determination processing is performed in both the first determination and the second determination in each of the above-mentioned embodiments, the leak determination processing may be performed in either the first determination or the second determination.

While the leak determination processing is performed based on the correspondence table 233 in which the waiting specified temperature is associated with both the thresholds in the first determination (the first threshold and the second threshold) and the thresholds in the second determination (the third threshold and the fourth threshold) in the above-mentioned second embodiment, the leak determination processing is not limited to this processing. The leak determination processing may be performed based on a correspondence table in which the waiting specified temperature is associated with at least one of the thresholds in the first determination and the thresholds in the second determination. Similarly, as for the thresholds in the first determination, the leak determination processing is not limited to the leak determination processing performed based on the correspondence table 233 in which the waiting specified temperature is associated with both the two types of thresholds, that is, the first threshold and the second threshold, and the leak determination processing may be performed based on a correspondence table in which the waiting specified temperature is associated with at least one of the first threshold and the second threshold as for the thresholds in the first determination. Furthermore, as for the thresholds in the second determination, the leak determination processing is not limited to the leak determination processing performed based on the correspondence table 233 in which the waiting specified temperature is associated with both the two types of thresholds, that is, the third threshold and the fourth threshold, and the leak determination processing may be performed based on a correspondence table in which the waiting specified temperature is associated with at least one of the third threshold and the fourth threshold as for the thresholds in the second determination.

While the flash heating unit 5 includes the 30 flash lamps FL in the above-mentioned embodiment, the number of flash lamps FL is not limited to 30, and the flash heating unit 5 may include any number of flash lamps FL. The flash lamps FL are not limited to the xenon flash lamps and may be krypton flash lamps. The number of halogen lamps HL of the halogen heating unit 4 is also not limited to 40, and the halogen heating unit 4 may include any number of halogen lamps HL. Furthermore, LEDs may be included in place of the flash lamps FL or the halogen lamps HL.

The substrate to be processed by the thermal processing apparatus 1 is not limited to the semiconductor wafer and may be a glass substrate used for a flat-panel display, such as a liquid crystal display, or a substrate for a solar cell.

Technology according to the present invention is applicable not only to a flash lamp annealing apparatus but also to a thermal processing apparatus using another light source, such as a single-substrate type lamp annealing apparatus using halogen lamps and a laser annealing apparatus, as long as the apparatus is an apparatus that reduces the pressure in the chamber. Technology according to the present invention is also applicable to a thermal processing apparatus using a heat source other than light irradiation, such as an apparatus to perform thermal processing using a hot plate, as long as the apparatus is the apparatus that reduces the pressure in the chamber. Furthermore, technology according to the present invention is broadly applicable not only to the thermal processing apparatus but also to an apparatus that reduces the pressure in the chamber to perform processing of the semiconductor wafer W.

While the invention has been shown and described in detail, the foregoing description is in all aspects illustrative and not restrictive. It is therefore understood that numerous modifications and variations can be devised without departing from the scope of the invention.

What is claimed is:

1. A leak determination method for use in a substrate processing apparatus for heating a substrate housed in a chamber, the leak determination method comprising:
a heating step of heating the substrate in the chamber;
a transport step of transporting the substrate from the chamber after the heating step;
a temperature measurement step of measuring an ambient temperature in the chamber; and
a leak determination step of performing leak determination processing of the chamber, wherein
after the substrate is transported from the chamber, waiting is continued until the ambient temperature decreases to a predetermined waiting specified temperature, and the leak determination processing is started when the ambient temperature reaches the waiting specified temperature.

2. The leak determination method according to claim 1, wherein
the leak determination step includes at least one of:
a first determination step of discharging gas from the chamber while stopping supply of gas into the chamber, and determining the presence or absence of a leak by whether a pressure in the chamber is reduced to a pressure less than a first threshold in a first time period; and
a second determination step of stopping supply and discharge of gas into and from the chamber, maintaining the chamber at the reduced pressure, and determining the presence or absence of the leak by whether the amount of the leak from the chamber in a second time period is less than a second threshold.

3. The leak determination method according to claim 2, wherein
a start of the second time period is later than a start of a containment time period during which supply and discharge of gas into and from the chamber are stopped, and an end of the containment time period and an end of the second time period coincide with each other.

4. The leak determination method according to claim 1, wherein
the waiting specified temperature is a room temperature.

5. The leak determination method according to claim 2, wherein
the waiting specified temperature is higher than a room temperature,
the leak determination method further comprises
a table creation step of creating a correspondence table in which the waiting specified temperature and at least one of the first threshold and the second threshold are associated with each other, and
in the leak determination step, at least one of the first threshold and the second threshold corresponding to the waiting specified temperature as specified is extracted from the correspondence table to perform the leak determination processing.

6. The leak determination method according to claim 1, further comprising
a scheduling step of setting time at which the leak determination step is performed.

7. The leak determination method according to claim 6, wherein
when the substrate is being heated in the chamber at reaching the time set in the scheduling step, the leak determination processing is started after heating of the substrate ends and the substrate is transported from the chamber.

8. The leak determination method according to claim 1, wherein
in the heating step, the substrate is heated by being irradiated with light from a continuous lighting lamp and a flash lamp.

9. A substrate processing apparatus for heating a substrate, the substrate processing apparatus comprising:
a chamber to house the substrate;
a heating unit to heat the substrate housed in the chamber;
a gas supply unit to supply gas into the chamber;
a gas discharge unit to discharge gas from the chamber;
a thermometer to measure an ambient temperature in the chamber;
a pressure gauge to measure a pressure in the chamber, wherein
after the substrate whose heating has ended is transported from the chamber, waiting is continued until the ambient temperature decreases to a predetermined waiting specified temperature, and leak determination processing of the chamber is started when the ambient temperature reaches the waiting specified temperature.

10. The substrate processing apparatus according to claim 9, wherein
the leak determination processing includes at least one of:
first determination of discharging gas from the chamber while stopping supply of gas into the chamber, and determining the presence or absence of a leak by whether a pressure in the chamber is reduced to a pressure less than a first threshold in a first time period; and
second determination of stopping supply and discharge of gas into and from the chamber, maintaining the chamber at the reduced pressure, and determining the presence or absence of the leak by whether the amount of the leak from the chamber in a second time period is less than a second threshold.

11. The substrate processing apparatus according to claim 10, wherein
a start of the second time period is later than a start of a containment time period during which supply and discharge of gas into and from the chamber are stopped, and an end of the containment time period and an end of the second time period coincide with each other.

12. The substrate processing apparatus according to claim 9, wherein
the waiting specified temperature is a room temperature.

13. The substrate processing apparatus according to claim 10, wherein
the waiting specified temperature is higher than a room temperature,
the substrate processing apparatus further comprises
a storage to store a correspondence table in which the waiting specified temperature and at least one of the first threshold and the second threshold are associated with each other, and
at least one of the first threshold and the second threshold corresponding to the waiting specified temperature as specified is extracted from the correspondence table to perform the leak determination processing.

14. The substrate processing apparatus according to claim 9, further comprising
a scheduling unit to set time at which the leak determination processing is performed.

15. The substrate processing apparatus according to claim 14, wherein
when the substrate is being heated in the chamber at reaching the time set by the scheduling unit, the leak determination processing is started after heating of the substrate ends and the substrate is transported from the chamber.

16. The substrate processing apparatus according to claim 9, wherein
the heating unit includes:
a continuous lighting lamp to irradiate the substrate with light; and
a flash lamp to irradiate the substrate with a flash of light.
